(19) United States
(12) Patent Application Publication
(10) Pub. No.: US 2015/0101659 A1
(43) Pub. Date: Apr. 16, 2015

(54) HETERO-CONTACT SOLAR CELL AND METHOD FOR THE PRODUCTION THEREOF

(71) Applicants: Giuseppe Citarella, Chemnitz (DE); Matthias Erdmann, Chemnitz (DE); Frank Wuensch, Berlin (DE); Martin Weinke, Hohenstein-Ernstthal (DE); Guillaume Wahli, Ecublens (CH)

(72) Inventors: Giuseppe Citarella, Chemnitz (DE); Matthias Erdmann, Chemnitz (DE); Frank Wuensch, Berlin (DE); Martin Weinke, Hohenstein-Ernstthal (DE); Guillaume Wahli, Ecublens (CH)

(73) Assignee: ROTH & RAU AG, HOHENSTEIN-ERNSTTHAL (DE)

(21) Appl. No.: 14/401,569

(22) PCT Filed: May 6, 2013
(86) PCT No.: PCT/IB2013/053610

§ 371 Date: Nov. 17, 2014

(30) Foreign Application Priority Data
May 16, 2012 (DE) 10 2012 104 289.6

(51) Int. Cl. H01L 31/0376; H01L 31/0224; H01L 31/20; H01L 31/072; H01L 31/065

(52) U.S. Cl. CPC H01L 31/0376; H01L 31/072; H01L 31/065; H01L 31/20; H01L 31/022441; H01L 31/022483; H01L 31/022475
USPC 136/255; 438/96

(57) ABSTRACT

A hetero-contact solar cell has a front side provided for an incidence of solar radiation. The solar cell has an absorber of a crystalline semiconductor material of a first conductivity type, an amorphous semiconductor layer of the first conductivity type doped more highly than the absorber and an electrically conductive, transparent front side conduction layer provided on the amorphous semiconductor layer. A front side contact is provided on the solar cell and has spaced-apart contact structures. An emitter of a second conductivity type opposite to the first conductivity type is provided on a back side. A back side contact is arranged on the back side. The emitter-related absorption losses of the solar cells can be eliminated by the back side contact having a back side contact layer extending over the surface of the back side, and the front side conduction layer containing a specific resistance from 7×10⁻⁴ to 50×10⁻⁴ Ωcm.

The present invention relates to a hetero-contact solar cell, a front side of which being provided for an incidence of solar radiation, said cell comprising: an absorber of a crystalline semiconductor material of a first conductivity type, an amorphous semiconductor layer of a first conductivity type doped more highly than the absorber and being provided on the front side of the hetero-contact solar cell, an electrically conductive, transparent front side conducting layer being provided on the front side of the doped amorphous semiconductor layer of the first conductivity type, a front side contact on the front side of the hetero-contact solar cell having spaced-apart contact structures, an emitter of a second conductivity type opposite to the first conductivity type being on a back side of the hetero-contact solar cell, and a back side contact being arranged on the back side of the hetero-contact solar cell. The invention further relates to a method for producing such a hetero-contact solar cell, in the front side of which an incidence of solar radiation is provided, wherein an absorber of a crystalline semiconductor material of a first conductivity type is provided, an amorphous semiconductor layer doped more highly than the absorber is deposited on the front side of the hetero-contact solar cell, an electrically conductive, transparent front side conducting layer is deposited on the front side of the doped amorphous semiconductor layer of the first conductivity type, a front side contact having spaced-apart contact structures is provided on the front side of the hetero-contact solar cell, an emitter of a second conductivity type opposite to the first conductivity type is deposited on a back side of the hetero-contact solar cell, and a back side contact is provided on the back side of the hetero-contact solar cell.

Standard hetero-contact solar cells comprise a structure, which has an emitter of amorphous, p-doped silicon, and a transparent, conductive oxide layer (TCO layer) below finger-shaped front contacts being arranged on the light-turned side of a central absorber of crystalline, n-doped silicon. By the emitter, being provided on the light-turned front side of the absorber, radiation is absorbed, which cannot reach the absorber. On the shaded back side of the hetero-contact solar cell, an amorphous, n⁺-doped silicon layer, with a full-faced back side contact is provided on the absorber for forming a surface field (“Back Surface Field”, BSF) reflecting minority charge carriers.

To reduce the losses of hetero-contact solar cells with conventional layer structure geometry with an emitter on the light-turned front side of the absorber, different approaches are known in the state of the art. One of these approaches is to arrange the emitter on the shaded side of the absorber. In the document U.S. Pat. No. 7,199,395 B2, the emitter provided on the back side is stripe-shaped and interlaced with amorphous stripes of opposite doping while forming an interdigitated structure. The differently doped regions are contacted by Ohmic contact structures on the shaded back side of the solar cell. Since both the emitter structures as well as the back surface field structures are provided and have to be contacted on the back side of the solar cell, the technology involved therewith is very complex. Furthermore, an additional passivation layer has also to be provided on the light-turned solar cell front side of such solar cells to reduce the re-combination of light-generated charge carriers on the front side of the solar cell while forming a so-called FSF (“Front Surface Field”).

Another approach to reduce the losses caused by the emitters arranged on the front side is adopted in the document WO 2006/111138 A1. The hetero-contact solar cell described in said document comprises an inverted layer structure geometry, and thus an inverted hetero-contact compared to the hetero-contact solar cells known to date. Thereby, the amorphous emitter is provided on the shaded back side of the absorber. Since the intensity of the incident light is largely reduced behind the absorber, hardly any radiation can be absorbed by the emitter, whereby the absorption losses are kept to a minimum. The front side of the absorber of said hetero-contact solar cell has only one single dielectric, transparent anti-reflection layer, which simultaneously serves as electrically functioning passivation layer, thereby preventing a charge carrier re-combination on the absorber by saturating dangling bonds and forming a minority charge carrier back scattering surface field (“Front Surface Field”, FSF) by means of the charge contained in the passivation layer. Hence, said hetero-contact solar cell does not need high-doped silicon FSF layers on its front side.

Consequently, when using such a hetero-contact solar cell, the emitter is not provided as amorphous, stripe-shaped emitter as disclosed in the document U.S. Pat. No. 7,199,395 B2 but as an amorphous emitter layer provided over the entire wafer back side, being easily producible and contactable. Another advantage is emphasized in the document WO 2006/111138 A1, indicating that by separating the transparent anti-reflection layer from the emitter, their layer thicknesses can be optimized independently to one another. This way, the emitter on the shaded back side of the absorber can be provided thicker than on the light-turned front side in order to produce a stable space-charge region, and thereby improving the electrical properties at the interface between emitter and absorber. In the document WO 2006/111138 A1, silicon nitride is suggested as particular advantageous material for forming the anti-reflection layer.

The other Ohmic contact structure being on the back side of the known hetero-contact solar cell is provided on a large area of the emitter. Thereby, it is explicitly mentioned in the document WO 2006/111138 A1 that a transparent, conductive oxide layer (TCO) is not required as electrode for contacting the emitter. The electrode's function as current dispersion is realized by a direct, full-area metallization.

The charge carriers, being generated in the absorber and separated in the space-charge region at the hetero-contact between crystalline absorber and amorphous emitter, are discharged by the fine contact grid provided on the solar cell's front side and the extensive contact structure provided on the solar cell's back side of said hetero-contact solar cell.

In the document EP 1 696 492 A1, a method for the edge insulation of hetero-contact solar cells is described. Amongst other things, a cell configuration with a back-sided emitter arrangement is disclosed therein. In the mentioned embodiment, on the emitter, a transparent back side electrode is provided, on which—in turn—collector electrodes, being spaced to one another and formed of conductive paste, are provided on the back side of the solar cell. Regarding the mode of operation of such a hetero-contact solar cell, the document EP 1 696 492 A1 discloses that the n-type absorber and the n-type a-Si:H-layer can collect the electrodes more efficiently than the p-type emitter the holes, which are generated in the absorber by light irradiation. From a physical point of view, however, this is incomprehensible as different collecting efficiencies of electrons on the n-type-doped side and holes on the p-type-doped side would lead to a charging of the device which would be in contrast to the neutrality principle. Furthermore, it is argued in the document EP 1 696 492 A1 that by the alleged improved collection of electrons, the metallization on the n-type side of the hetero-contact solar cells could be thinned out, whereby narrower busbars and a smaller number of fingers could be used. As a result, by less shading, a higher current could be achieved.

The above mentioned hetero-contact solar cells with a back side-arranged emitter have the advantage, compared to standard hetero-contact solar cells, that the light energy entering the solar cell can be converted into electrical energy with significantly higher efficiency because no emitter-related absorption losses occur. In addition, for instance, the hetero-contact solar cell, mentioned in the document WO 2006/111138 A1, can be realized with a relatively simple technology. This technology, however, is significantly different to the technology for producing standard hetero-contact solar cells so that the existing device concepts have to be changed, respectively, single process modules can no longer be used and others, in turn, have to be newly installed.

The object of the present invention is therefore, to provide a hetero-contact solar cell concept and a method for the production of such solar cells, with which the emitter-related absorption losses at the hetero-contact solar cells can be eliminated by still using standard technologies for the production of said hetero-contact solar cells.

On the one hand, the object is solved by a hetero-contact solar cell of the above mentioned type, at which the back side contact comprises a back side contact layer extending over the surface of the back side of the hetero-contact solar cell, and the front side conduction layer comprises a specific resistance in a range from 7×10⁻⁴ to 50×10⁻⁴ Ωcm, preferred over 11×10⁻⁴ Ωcm, preferably of over 14×10⁻⁴ Ωcm.

Thereby, for the production of the hetero-contact solar cell according to the invention, the same step sequence as for the production of a non-inverted standard hetero-contact solar cell can be used, although the emitter of the hetero-contact solar cell according to the invention is provided on the back side behind the absorber. Because of the emitter provided on the solar cell's back side, no emitter-related absorption losses occur in the hetero-contact solar cell according to the invention. Furthermore, the emitter is provided over the entire surface of the hetero-contact solar cell according to the invention, whereby the emitter can be contacted over the entire surface of the hetero-contact solar cell's back side, and thus a relatively simple emitter production and contact technology is enabled.

In a preferred embodiment of the hetero-contact solar cell according to the invention, an electrical conductive, transparent back side conduction layer is provided between the emitter and the back side contact, comprising a specific resistance in a range from 7×10⁴ to 50×10⁴ Ωcm, preferred over 11×10⁻⁴ Ωcm, preferably of over 14×10⁻⁴ Ωcm.

Hence, the front side and, if necessary, also the back side conduction layer of the hetero-contact solar cell according to the invention are formed of conventional TCO layers with a relatively high specific resistance. Since majority charge carriers are collected by the front side conduction layer in the hetero-contact solar cell according to the invention, the conductivity of the front side conduction layer (front-sided TCO layer) is supported by the conductivity of the absorber (substrate). Due to the transverse conductivity of the absorber, the current of the majority charge carriers can be led through the cross-section of the cell to the contact structures (contact fingers) of the front side contact, so that the conductivity of the front side conduction layer does not need to meet high demands. Accordingly, the front side conduction layer (front-sided TCO layer) can be provided with a high transparency without negatively influencing the series resistance of the solar cell. By optimizing the transparency of the front side conduction layer, the values for the short circuit current density J_{SC} of the hetero-contact solar cell according to the invention can be improved. Since the transparency of TCO layers is inversely proportional to the conductivity of such layers, the front side conduction layer of the hetero-contact solar cell according to the invention, can, because the conductivity of the front side conduction layer can be kept at a low level by the support of the conductivity of the absorber, be built with a high optical transparency in the suggested resistance region according to the invention.

Hence, in the present invention, by the arrangement of the emitter on the back side of the solar cell, a high-Ohmic TCO layer (front side conduction layer) on the front side of the solar cell can be provided without the fill factor (FF) of the solar cell suffering from an increased series resistance of the solar cell. Such a high-Ohmic TCO layer would lead to huge fill factor losses in a standard hetero-contact solar cell. Since the series resistance of the layer sequence at the front side of the solar cell according to the invention results from the resistance of the front side conduction layer (front-sided TCO layer) and the resistance of the absorber, and since the conductivity of the absorber, for instance, is adjustable very high by using low-Ohmic wafers respectively a high injection level of the used cells, a low series resistance at the front side of the hetero-contact solar cell is the overall result.

In the hetero-contact solar cell according to the invention, the good conductivity of the absorber can be used for the following effect: standard solar cells with front-sided emitter, which can be provided with a diffused emitter as well as with a hetero-contact, always have a part of series residual resistance, which is significantly influenced by the conductivity of the emitter with regard to a standard solar cell with a diffused front-sided emitter and by the conductivity of the front-sided TCO layer with regard to a hetero-contact solar cell. Thereby, in said standard solar cells, the contribution of the absorber and the solar cell's back side to the series resistance is very low compared to the contribution of the series resistance, which results from the low conductivity of the layers at the front side of the solar cell, to say the conductivity of the emitter in a standard solar cell with a diffused emitter or the conductivity of the TCO layer in a standard hetero-contact solar cell with a front-sided emitter. Said series resistance's loss of the known standard solar cells has to be accepted as it cannot be reduced significantly. In contrast, in the hetero-contact solar cell according to the invention, the conductivity of the absorber supports the conductivity of the front side conduction layer (front-sided TCO layer). According to the conductivity, which can be easily increased, of the substrate used to form the absorber, the above mentioned input of the series resistance of the conductivity of the front side conduction layer, which is conjointly determined in the hetero-contact solar cell by the conductivity of the front-sided TCO layer (front side conduction layer) and the conductivity of the absorber, can be reduced dramatically. It is therefore possible to provide the hetero-contact solar cell according to the invention by means of a simple planar technology, whereby especially with regard to the solar cell back side, no structuring by forming interdigitated regions on the solar cell back side, as known, for instance, from the document U.S. Pat. No. 7,199,395 B2 respectively DE 100 45 249 A1, is necessary.

Basically, a potential TCO layer (back side conduction layer) on the back side of the hetero-contact solar cell according to the invention can also be provided with relatively low electrical conductivity, since the solar cell back side is electrically contacted by the back side conduction layer such as a metal layer over the entire surface. Accordingly, the back side conduction layer can also be provided—within the scope of the resistance range according to the invention—with an increased transparency, whereby particularly the IR (infrared) losses at the solar cell back side are reduced.

According to a preferred embodiment of the invention-related hetero-contact solar cell, the front side conduction layer and the back side conduction layer comprise the same specific optical and electrical properties. Thereby it is possible that the front side conduction layer and the back side conduction layer can be produced from the same material, preferably by using the same process. This way, for the production of the front side conduction layer and the back side conduction layer, the same deposition device can be used, said device can be provided in a relatively simple form since the optical and electrical properties of the front side conduction layer and the back side conduction layer does not have to be adjusted separately in said variant of the hetero-contact solar cell.

It is particularly of advantage, if the front side conduction layer and the back side conduction layer comprise the same dopings, and thus the same specific resistance. Thereby it is possible to produce the front side conduction layer and the back side conduction layer in one and the same deposition process by using same materials and same dopings. Thereby, a particularly efficient producibility of the hetero-contact solar cell according to the invention is provided. Furthermore, transparency and electrical properties of the front side conduction layer and the back side conduction layer can be conjointly adjusted the same way and systematically, and thus optimizing the layer properties of both layers.

In another variant of the hetero-contact solar cell according to the invention, the front side conduction layer and the back side conduction layer can also be differently doped. Thereby, the optical and electrical properties of the front side conduction layer and the back side conduction layer can be differently adjusted.

Preferably, the front side conduction layer and the back side conduction layer comprise a transmission of over 85% in the wave length range from 550 nm to 1200 nm.

At such transparent front side conduction layers and back side conduction layers, a high efficiency of the hetero-contact solar cell according to the invention can be reached, as thereby, on the one hand, the short-circuit current density can be optimized and, on the other hand, optical losses in the infrared on the solar cell back side can be reduced.

In a special embodiment of the present invention, the back side conduction layer of the hetero-contact solar cell comprises a higher transmission in the infrared spectral region than in the front side conduction layer. Thereby, the optical losses in the infrared on the back side of the solar cell are reduced, while the front side conduction layer can be provided with optimized optical and electrical properties.

According to a further embodiment of the hetero-contact solar cell according to the invention, the front side conduction layer and the back side conduction layer comprise at least one indium-tin-oxide-layer (ITO layer). ITO layers have a very good transparency with simultaneously high electrical conductivity, and thus are very suitable to provide a hetero-contact solar cell with high efficiency.

In another variant of the present invention, the front side conduction layer and back side conduction layer of the hetero-contact solar cell can comprise at least one aluminum doped zinc-oxide-layer (ZnO:Al layer). ZnO—Al is cheaper than ITO, has, however, a lower transparency, when the layer shall be well-conductive in such a way that their conductivity for a hetero-contact solar cell is sufficient. Since, as discussed above, the conductivity of the front side conduction layer and the back side conduction layer of the hetero-contact solar cell according to the invention can be thoroughly lower than of TCO layers of standard hetero-contact solar cells, the doping of the ZnO-layer can be adjusted low, and thus a high transparency can be reached. Thereby, the usage of zinc-oxide-layers doped with aluminum for forming the front side conduction layers and the back side conduction layers can be quite profitable.

It can also be advantageous, when the front side conduction layer and the back side conduction layer of the hetero-contact solar cell of the invention comprise at least one indium-oxide-layer (IO layer). IO layers can also be provided in a good conductivity-transparency ratio.

In a preferred embodiment of the hetero-contact solar cell according to the invention, the first conduction type, to say the conduction type of the absorber and the doped amorphous semiconductor layer provided on the front side of the absorber, is provided by an n-doping, and the second conduction type, to say the conduction type of the emitter layer, is provided by a p-doping. Although, it is basically possible to dope the absorber with a p-type and the emitter with an n-type, the above mentioned variant of a hetero-contact solar cell is particularly efficient since an n-conducting absorber of silicon comprises very good transport properties and a high charge carrier lifetime. The majority charge carriers, which are electrons in an n-conducting absorber, can thereby be advantageously conducted through the absorber to the front side contact.

According to a preferred variant of the hetero-contact solar cell according to the invention, an amorphous, intrinsic, to say not-doped, semiconductor layer between the absorber and the doped, amorphous semiconductor layer on the front side, and/or between the absorber and the emitter is provided. The intrinsic semiconductor layer is typically provided very thinly, to say with a layer thickness of few nanometers. Because of the additionally provided intrinsic semiconductor layer(s), the interface characteristic between the respective layers is improved and the efficiency losses are reduced as there are only minimal defects in the intrinsic layers, at which recombinations of produced charge carriers can occur.

For instance, the amorphous intrinsic semiconductor layer is a hydrogenous amorphous silicon layer.

Advantageously, the amorphous doped semiconductor layer and/or the emitter layer is a hydrogenous silicon layer or a SiOₓ-layer with x≦2. Thereby, the amorphous doped semiconductor layer and the emitter are accordingly doped oppositely.

It is particularly of advantage, when the emitter of the hetero-contact solar cell according to the invention is provided unstructured, to say as a continuous layer. Thereby, the emitter can be produced particularly easy and subsequently contacted.

The object of the invention is further solved by a method for the production of a hetero-contact solar cell according to the above mentioned type, wherein such materials are chosen for the deposition of the front side conduction layer that the specific resistance of said layer is in a range from 7×10⁻⁴ to 50×10⁻⁴ Ωcm, preferred of over 11×10⁻⁴ Ωcm, preferably of over 14×10⁻⁴ Ωcm, and at which the back side contact is deposited as a back side contact layer extending over the surface of the back side of the hetero-contact solar cell.

In a preferred embodiment of the method according to the invention, an electrical conductive, transparent back side conduction layer is additionally provided between the emitter and the back side contact, wherein such materials are chosen for the deposition of the back side conduction layer that the specific resistance of said layer is in a range from 7×10⁻⁴ to 50×10⁻⁴ Ωcm, preferred over 11×10⁻⁴ Ωcm, preferably of over 14×10⁻⁴ Ωcm.

Thereby, it is particularly of advantage, when the front side conduction layer and the back side conduction layer are simultaneously produced in the same deposition chamber.

By the method according to the invention, standard processes for the production of hetero-contact solar cells are used, but with the difference that by the method according to the invention, an inverted hetero-contact solar cell is produced, at which the emitter is provided on the back side, to say on the shaded side, of the hetero-contact solar cell. Thereby, in contrast to the technology disclosed in the document WO 2006/111138 A1, electrical conductive, transparent layers, to say typically TCO layers, are provided on the front side as well as on the back side of the hetero-contact solar cell structure. The TCO layers described as front side conduction layers respectively back side conduction layers comprise a relatively high specific resistance. The effect, however, is in this case not negatively due to the absorber having such a high conductivity that the low conductivity of the front side conduction layer on the solar cell's front side can be thereby compensated. The relatively high specific resistance of the back side conduction layer on the back side of the solar cell is also not critical because it is compensated by the back side contact layer extending over the entire surface of the back side of the hetero-contact solar cell.

Due to the emitter of the method according to invention being provided on the back side of the hetero-contact solar cell, behind the absorber, there are no emitter-related absorption losses, and thus a solar cell with high efficiency can be provided. Since the emitter is omitted on the solar cell's front side, the demands on the layers on the solar cell's front side, to say on the absorber, with regard to the layer resistance do not have to be as high as is necessary in standard hetero-contact solar cells with a non-inverted structure. Thereby, materials can be used for the front side conduction layer with poor conductivity at the same transparency, but, for instance, with lower material costs. Moreover, since the back side conduction layer on the solar cell's backside can be provided with a relatively low conductivity, this layer can be provided with higher transparency, particularly in the infrared range. Thereby, the infrared losses on the solar cell's back side can be reduced.

Hence, the method according to the invention can be carried out by using already existing, optimized solar cell production devices and solar cell production steps, wherein hetero-contact solar cells are produced, which comprise an increased efficiency compared to standard hetero-contact solar cells, due to their inverted structure. Thereby, the emitter can be provided in a simple way, for instance, as unstructured layer, on the solar cell back side, and can be contacted there, also in a simple way, by means of the back side contact layer extending over the surface of the back side of the hetero-contact solar cell.

In a particularly advantageous embodiment of the method according to the invention, targets of the same material are used for the deposition of the front side conduction layer and for the deposition of the back side conduction layer. Thus, the front side conduction layer as well as the back side conduction layer can be produced by a single process in a single device. Thereby, particularly low production costs for the production of hetero-contact solar cells can be reached. This way, the front side conduction layer and the back side conduction layer can be provided with the same or very similar optical and electrical properties; it is of great advantage, when the cell concept can reach the highest efficiency also under said conditions.

In another variant of the method according to the invention, it can also be beneficial, when targets of different material and/or with different doping material concentration are used for the deposition of the front side conduction layer and the back side conduction layer. In this case, the properties of the front side conduction layer, on the one hand, and the back side conduction layer, on the other hand, can be systematically adjusted in order to provide optimized hetero-contact solar cells for defined utilizations.

The targets can be chosen, for instance, from indium-tin-oxide, from zinc-oxide doped with aluminum, and/or from indium-oxide. In addition, however, there are many other suitable materials in order to produce the front side conduction layer and the back side conduction layer. The above mentioned TCO materials, however, are characterized by their advantageous optical and electrical properties, wherein particularly zinc-oxide doped with aluminum is linked to relatively low costs.

In a further embodiment of the method according to the invention, the O₂ flow used in the deposition chamber is the same as for the deposition of the front side conduction layer and for the deposition of the back side conduction layer respectively the O₂ concentration, which is used for doping said layers. Thereby, the doping of the TCO layers (front side conduction layer and back side conduction layer) is the same or very similar at the front side and the back side of the provided hetero-contact solar cell. Hence, only one oxygen gas input in a single chamber without gas separations can be implemented in the deposition of the front side conduction layer and the back side conduction layer, whereby the device as well as the process costs can be kept at a minimum level. Hereby, the front side conduction layer and the backside conduction layer are deposited at the same gas conditions, and thus provided with the same or very similar electrical and optical properties. The latter is rather disadvantageously for the production of hetero-contact solar cells according to the state of the art as it is there desired to provide the TCO layer on the solar cell front side preferably conductive, and thus also producing a conductive TCO layer on the solar cell back side, whereby, on the other hand, infrared losses occur on the solar cell back side. Since it is possible to provide the TCO layer on the solar cell front side, to say the transparent front side conduction layer, by the method according to the invention less conductive and instead more transparent, because the conductivity of the absorber enhances the conductivity of the transparent front side conduction layer, the TCO layer on the solar cell back side, to say the back side conduction layer, is providable with higher transparency by the method according to the invention, whereby the infrared losses on the solar cell back side can be reduced.

Preferred embodiments of the present invention, their structure, function, and advantages are explained by figures in more detail as follows, whereby

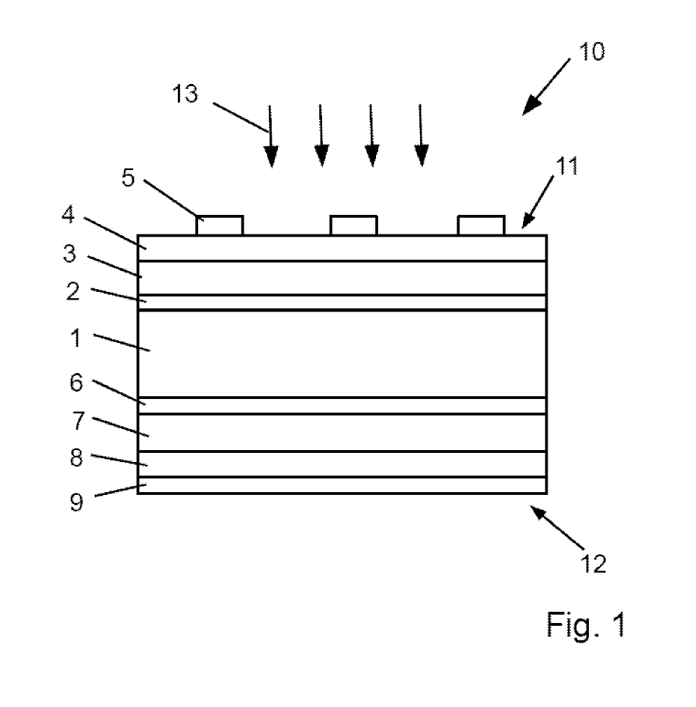

FIG. 1 schematically shows a possible structure of a hetero-contact solar cell of the present invention in a cross-section through its layer structure; and

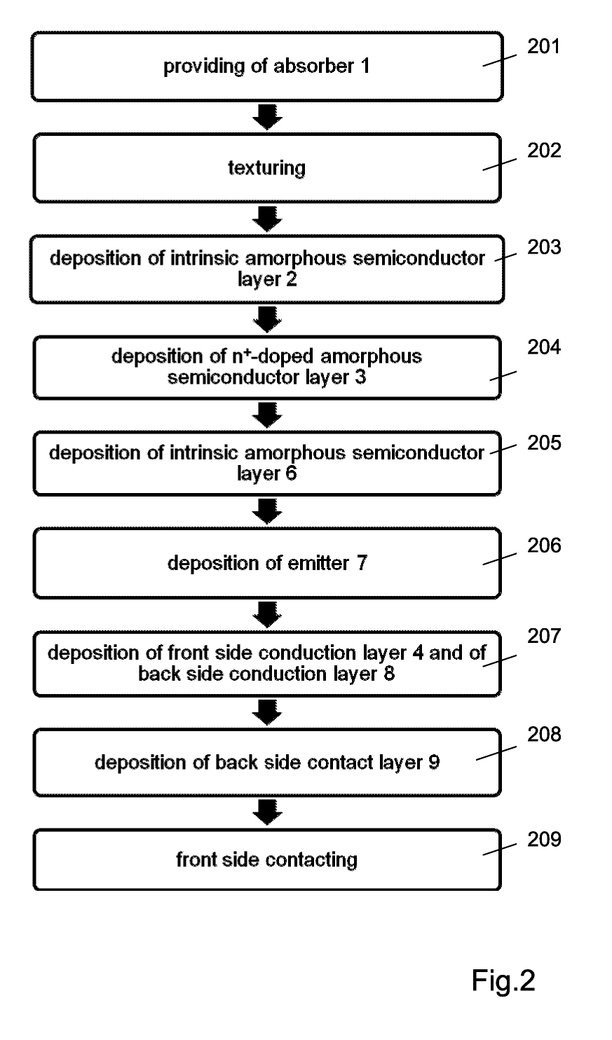

FIG. 2 schematically shows a possible process sequence for the production of a hetero-contact solar cell according to the invention and according to the method of the invention.

FIG. 1 schematically shows an embodiment of a hetero-contact solar cell 10 according to the invention in a cross-section through its layer sequence.

The hetero-contact solar cell 10 comprises a front side 11, in which an incidence of solar radiation 13 is provided. The side of the hetero-contact solar cell 10 opposite to the front side 11 is the back side 12.

The hetero-contact solar cell 10 comprises a substrate respectively an absorber 1. In the shown embodiment, the absorber 1 is n-doped and is of crystalline silicon. In other, non-shown embodiments of the present invention, the absorber 1 can also be of another semiconductive material. Preferably, this material is mono-crystalline, but can also be poly-, multi-, or micro-crystalline. Furthermore, the absorber 1 can also be p-doped in other variants of the present invention. Thereby, there are different possibilities when choosing the used dopants, respectively. For instance, the absorber 1 shown in FIG. 1 can be n-doped with phosphor.

On the front-sided surface of the absorber 1 of the embodiment shown in FIG. 1, an amorphous, intrinsic, to say non-doped, semiconductor layer 2 is provided. The semiconductor layer 2 of the example shown is an amorphous, intrinsic, hydrogenous silicon layer, but can also be provided of another suitable amorphous, intrinsic semiconductor material in other embodiments of the invention, according to the absorber material used.

In other, non-shown embodiments of the present invention, the amorphous, intrinsic semiconductor layer 2 can also be omitted.

On the amorphous, intrinsic semiconductor layer 2 of the embodiment of FIG. 2, an n⁺-doped, amorphous semiconductor layer 3 is provided. That is, the doped amorphous semiconductor layer 3 comprises a higher doping than the absorber 1. In the embodiment shown in FIG. 1, the doped, amorphous semiconductor layer 3 is comprised of hydrogenous, amorphous silicon (a-Si:H) with an n-type doping such as a phosphor-doping. In other, non-shown embodiments of the present invention other suitable semiconductor materials and/or suitable dopants can be used for the doped, amorphous semiconductor layer 3 depending on the choice of material for the absorber 1.

Above the doped, amorphous semiconductor layer 3, on the front side 11 of the hetero-contact solar cell 10, a transparent front side conduction layer 4 is provided. The transparent front side conduction layer 4 is a TCO (Transparent Conductive Oxide) layer. In the embodiment shown in FIG. 1, the transparent front side conduction layer 4 is comprised of aluminum doped zinc-oxide, but can also be, for instance, an indium-tin-oxide-layer or an indium-oxide-layer in other, non-shown variants of the present invention.

The transparent front side conduction layer 4 comprises a layer resistance in a range from 7×10⁻⁴ to 50×10⁻⁴ Ωcm. The layer thickness of the front side conduction layer is optimized to λ/4n of the hetero-contact solar cell's incident light irradiation, wherein n represents the refraction index of the front side conduction layer 4. In the shown embodiment, the layer thickness of the transparent front side conduction layer 4 ranges between 70 and 120 nm.

Furthermore, a front side contact with several spaced-apart contact structures 5 is provided on the front side 11 of the hetero-contact solar cell 10 on the transparent front side conduction layer 4. The contact structures 5 are also often called contact fingers among experts. The contact structures 5 can also be comprised, for instance, of silver. Basically, however, other, well-conductive materials such as metals can be considered for forming the contact structures 5.

On the back-sided surface of the absorber 1, a thin intrinsic, to say non-doped, amorphous semiconductor layer 6 is provided in the hetero-contact solar cell 10 of FIG. 1. The intrinsic, amorphous semiconductor layer 6 has the same respectively similar properties as the above mentioned intrinsic, amorphous layer 2; therefore, it shall be referred to the above descriptions on the intrinsic, amorphous semiconductor layer 2, which also apply for the intrinsic, amorphous semiconductor layer 6. In other, non-shown embodiments of the invention, the intrinsic, amorphous semiconductor layer 6 can also be omitted.

On the intrinsic, amorphous semiconductor layer 6, an emitter 7 is provided. The emitter 7 is of p⁺-doped amorphous silicon in the example of FIG. 1. In the shown embodiment, the emitter 7 is of hydrogenous amorphous silicon (a:SiH) with a p-type-doping. The emitter 7 is provided behind the absorber 1 from the perspective of the solar radiation 13 entering the hetero-contact solar cell 10. Hence, practically no light entering the absorber 1 can be absorbed by the emitter 7. Accordingly, the emitter 7 can be provided with a suitable thickness, which then, if the emitter, as it is the case in standard hetero-contact solar cells, is provided on the front side, is only possible in a limited way, in order to keep the absorption losses caused by the emitter at a minimum level. Moreover, the emitter 7 can be provided with a relatively high doping, thus having an advantageous electrical conductivity. The latter is also not possible in standard hetero-contact solar cells because an increased doping results in a poorer transparency, which in turn has a negative effect on the solar cell front side, but is not relevant for the emitter 7 of the present invention as being provided on the shaded side of the hetero-contact solar cell 10 behind the absorber 1. The emitter 7 is provided as a continuous layer on the absorber 1 in the example of FIG. 1.

On the back-sided surface of the emitter 7, a back side conduction layer 8 is provided in the hetero-contact solar cell 10. The back side conduction layer 8 is a TCO layer, to say, an electrically conductive, transparent oxide layer. In the embodiment of FIG. 1, the back side conduction layer 8 is of aluminum doped zinc-oxide. In other, non-shown embodiments of the present invention, an indium-tin-oxide-layer (ITO layer), an indium-oxide-layer, or another suitable TCO layer can be used to form the back side conduction layer 8.

The back side conduction layer 8 comprises, particularly in the infrared region, a high transparency. Preferably, the transmission of the above mentioned front side conduction layer 4 and the back side conduction layer 8 is over 85% in the wave length range from 550 nm to 1200 nm.

The back side conduction layer 8 is provided as unstructured layer on the emitter layer 7. It serves as electrode for collecting the charge carriers generated and separated in the space charge region between absorber 1 and emitter 7. Said charge carriers are transmitted from the back side conduction layer 8 to the back side contact being provided on the back side conduction layer 8 on the back side 12 of the hetero-contact solar cell 10. The back side contact of the hetero-contact solar cell 10 comprises a back side contact layer 9 extending over the entire surface of the back side conduction layer 8. The back side contact layer 9 can be, for instance, of silver. Basically, other, very well-conductive materials such as various metals are, however, also suitable to form the back side contact layer 9.

In other, non-shown embodiments of the present invention, the back side conduction layer 8 can also be omitted, and thus the back side contact layer 9 can be directly provided on the emitter 7. In this case, in which the TCO layer mentioned above as the back side conduction layer 8 is omitted at the back side of the solar cell, a full-face metallization, to say a deposition of the back side contact layer 9 over the entire surface, at the solar cell back side is necessary. If however, as mentioned above, a back side conduction layer 8 is provided between the emitter 7 and the back side contact layer 9, it is possible to provide the back side contact layer 9 as metallization over the entire surface or as structures with fingers, as the contact structure 5 on the solar cell front side.

FIG. 2 schematically shows a possible process sequence for implementing the method according to the invention for the production of a hetero-contact solar cell 10 as is schematically shown, for instance, in FIG. 1.

In the process sequence of FIG. 2, in a first step 201, an absorber 1 is provided. The absorber 1 is, as mentioned above, a suitable semiconductor substrate, which is in the embodiment of FIG. 2, for instance, an n-doped silicon substrate.

In step 202, a surface preparation of the absorber 1 is carried out among other things, whereby the surface of the absorber 1 is textured. The texturing serves to increase the light absorption in the provided hetero-contact solar cell 10 by reducing its reflection. The texturing is followed by a multi-stage cleaning.

In the following process step 203, the intrinsic, amorphous layer 2 in form of a thin, hydrogenous, amorphous, intrinsic silicon layer is deposited on the front side of the absorber 1.

This is followed by a step 204, in which a deposition of the doped amorphous semiconductor layer 3 on the intrinsic amorphous layer is carried out. In the shown embodiment, the doped amorphous semiconductor layer 3 is n⁺-doped.

In the process step 205, an intrinsic, amorphous semiconductor layer 6 in form of a hydrogenous, amorphous intrinsic silicon layer is deposited on the back side of the absorber 1. The p⁺-doped emitter 7 consisting of hydrogenous amorphous silicon is deposited on the intrinsic amorphous semiconductor layer 6 in a process step 206.

In other, also suitable method variants of the method according to the invention, the above mentioned sequence for depositing the intrinsic and the doped amorphous semiconductor layers 2, 3, 6, and 7 can also be done in a different sequence. For instance, firstly, the intrinsic amorphous semiconductor layer 6 can be deposited on the back side of the absorber 1, followed by depositing the emitter 7 thereon, while then the intrinsic amorphous semiconductor layer 2 is deposited on the front side of the absorber 1 and the n⁺-doped amorphous semiconductor layer 3 is deposited thereon.

In the following single process step 207, the front side conduction layer 4 (TCO front side) and the back side conduction layer 8 (TCO back side) are deposited by implementing a PVD (physical vapor deposition) process. In the exemplary embodiment, both layers 4 and 8 are deposited in the same process chamber, with a single O₂ concentration in the chamber, which influences the doping of the TCO layer on the front side as well as that on the back side, with the result that both layers 4 and 8 have the same or very similar optical and electrical properties.

The formation of the back side contact is carried out by deposition of the back side contact layer 9 on the back side conduction layer 8 in the process step 208 by implementing PVD processes or screen printing or other metal deposition processes (e.g. plating etc.). The front side contact is carried out in the process step 209 by screen printing or other metal deposition processes (e.g. plating etc.) of contact structures.

As can be seen, principally, the above mentioned steps are all applicable for the production of standard hetero-contact solar cells. As a result, the process steps and their related devices for the production of the hetero-contact solar cell 10 according to the invention do not have to be modified compared to process sequences of standard hetero-contact solar cells. Only simple adjustments of the process parameters have to be made. However, with the above mentioned technology, an inverted hetero-contact solar cell structure (back-hetero-junction) is provided, at which the emitter-related absorption losses of standard hetero-contact solar cells are not present, and thus the efficiency of the producible hetero-contact solar cell 10 is very high. On basis of said advantages of the method sequence according to the invention, and hence the hetero-contact solar cell 10 producible, the usage of different indeed efficient-increasing but more expensive materials can be abandoned, for instance, to reduce the costs. For instance, instead of relatively cost-intensive ITO layers for the production of the transparent front side conduction layer 4 respectively the transparent back side conduction layer 8, cheaper materials such as aluminum doped zinc-oxide can be used.

Due to the back-hetero-junction solar cell concept used in the invention, the emitter 7 can be optimized with regard to its layer thickness and/or its doping by forming particularly advantageous electrical properties such as maximum open circuit voltage (V_{OC}). The latter is not the case for standard hetero-contact solar cells because a compromise of the emitter's layer thickness being provided between open circuit voltage (V_{OC}) and short circuit density (J_{SC}) has always to be found.

The solar cell production method according to the invention also allows, for instance, polishing the back side 12 of the hetero-contact solar cell 10. In this case, the advantage of the back side polish concerning the back side passivation is even bigger than in conventional hetero-junction solar cells because the emitter is provided on the polished back side: a smaller surface as feature for a better passivation is of more advantage on the emitter than on the surface field opposite to the emitter.

1-23. (canceled)

24. A hetero-contact solar cell having a front side provided for an incidence of solar radiation, the hetero-contact solar cell comprising:
an absorber of a crystalline semiconductor material of a first conductivity type;
an amorphous semiconductor layer of the first conductivity type doped more highly than said absorber and disposed on the front side of the hetero-contact solar cell;
a front side contact provided on the front side of the hetero-contact solar cell and having spaced-apart contact structures;
a front-sided transparent front side cover layer disposed on said amorphous semiconductor layer of the first conductivity type, said front-sided transparent front side cover layer is an electrically conductive, transparent front side conduction layer disposed between said amorphous semiconductor layer and said front side contact, said front side conduction layer having a specific resistance in a range from 7×10⁻⁴ to 50×10⁻⁴ Ωcm;
an emitter of a second conductivity type being opposite to the first conductivity type and disposed on a back side of the hetero-contact solar cell; and
a back side contact provided on said back side of the hetero-contact solar cell, said back side contact containing a back side contact layer extending over an entire surface of said back side of the hetero-contact solar cell.

25. The hetero-contact solar cell according to claim 24, further comprising an electrically conductive, transparent back side conduction layer disposed between said emitter and said back side contact and having a specific resistance in a range from 7×10⁻⁴ to 50×10⁻⁴ Ωcm.

26. The hetero-contact solar cell according to claim 25, wherein said front side conduction layer and said back side conduction layer have the same specific optical and electrical properties.

27. The hetero-contact solar cell according to claim 26, wherein said front side conduction layer and said back side conduction layer have the same doping, and thus the same specific resistance.

28. The hetero-contact solar cell according to claim 25, wherein said front side conduction layer and said back side conduction layer are differently doped.

29. The hetero-contact solar cell according to claim 25, wherein said front side conduction layer and said back side conduction layer have a transmission of over 85% in a wave length range from 550 nm to 1200 nm.

30. The hetero-contact solar cell according to claim 25, wherein said back side conduction layer has a higher transmission than said front side conduction layer in an infrared spectral range.

31. The hetero-contact solar cell according to claim 25, wherein said front side conduction layer and/or said back side conduction layer has at least one indium-tin-oxide-layer.

32. The hetero-contact solar cell according to claim 25, wherein said front side conduction layer and/or said back side conduction layer contains at least one aluminum doped zinc-oxide-layer.

33. The hetero-contact solar cell according to claim 25, wherein said front side conduction layer and/or said back side conduction layer contains at least one indium-oxide-layer.

34. The hetero-contact solar cell according to claim 24, wherein the first conductivity type is provided by an n-doping and the second conductivity type by a p-doping.

35. The hetero-contact solar cell according to claim 24, further comprising an amorphous intrinsic semiconductor layer disposed between said absorber and said amorphous semiconductor layer and/or between said absorber and said emitter.

36. The hetero-contact solar cell according to claim 35, wherein said amorphous intrinsic semiconductor layer is a hydrogenous amorphous silicon layer.

37. The hetero-contact solar cell according to claim 24, wherein said amorphous semiconductor layer and/or said emitter is a hydrogenous silicon layer or a SiOₓ-layer with x≦2.

38. The hetero-contact solar cell according to claim 24, wherein said emitter is unstructured.

39. A method for producing a hetero-contact solar cell having a front side for receiving an incidence of solar radiation, which comprises the steps of:
providing an absorber of a crystalline semiconductor material of a first conductivity type;
depositing an amorphous semiconductor layer of a first conductivity type being more highly doped than the absorber on the front-side of the hetero-contact solar cell;
depositing an electrically conductive, transparent front side conduction layer on the front side of the amorphous semiconductor layer of the first conductivity type, materials being chosen for the depositing of the front side conduction layer, such that a specific resistance of the front side conduction layer and amorphous semiconductor layer range from 7×10⁻⁴ to 50×10⁻⁴ Ωcm;
forming a front side contact having spaced-apart contact structures on the front side of the hetero-contact solar cell;
depositing an emitter of a second conductivity type opposite to the first conductivity type on a back side of the hetero-contact solar cell; and
forming a back side contact on the back side of the hetero-contact solar cell, the back side contact being deposited as a back side contact layer extending over a surface of the back side of the hetero-contact solar cell.

40. The method according to claim 39, which further comprises providing an electrically conductive, transparent back side conduction layer between the emitter and the back side contact, wherein such materials are used for a deposition of the back side conduction layer that a specific resistance of the back side conduction layer ranges from 7×10⁻⁴ to 50×10⁻⁴ Ωcm.

41. The method according to claim 40, which further comprises producing the front side conduction layer and the back side conduction layer simultaneously in a same deposition chamber.

42. The method according to claim 40, which further comprises using targets of a same material for a deposition of the front side conduction layer and for the deposition of the back side conduction layer.

43. The method according to claim 40, which further comprises using targets of different materials and/or with a different doping material concentration for a deposition of the front side conduction layer and the back side conduction layer.

44. The method according to claim 42, which further comprises selecting the targets from the group consisting of indium-tin-oxide, aluminum doped zinc-oxide and indium-oxide.

45. The method according to claim 41, which further comprises using for the deposition of the front side conduction layer and of the back side conduction layer, the same O₂-concentration for doping layers in a deposition chamber.

46. The method according to claim 39, which further comprises providing the absorber to be polished on its back side.
